(19) United States
(12) Patent Application Publication
(10) Pub. No.: US 2025/0224037 A1
(43) Pub. Date: Jul. 10, 2025

(54) VACUUM GATE VALVE AND VACUUM SYSTEM COMPRISING THE SAME

(71) Applicant: ASTROTEK CO., LTD., Cheongju-si, Chungchoengbuk-do (KR)

(72) Inventors: Eundo KIM, Asan-si, Chungcheongnam-do (KR); Miryeong LEE, Asan-si, Chungcheongnam-do (KR)

(21) Appl. No.: 18/848,911

(22) PCT Filed: Mar. 20, 2023
(86) PCT No.: PCT/KR2023/003647

§ 371 Date: Sep. 20, 2024

(30) Foreign Application Priority Data
Mar. 21, 2022 (KR) 10-2022-0034470

(51) Int. Cl. F16K 3/314; F16K 3/02; F16K 51/02

(52) U.S. Cl. CPC F16K 3/314; F16K 3/0263; F16K 51/02

(57) ABSTRACT

The present invention relates to a vacuum gate valve including a valve body in which an inlet and an outlet are formed, a blocking plate formed on a fluid passage between the inlet and the outlet, a driving unit which is installed on the valve body to be connected to the blocking plate and moves the blocking plate to open or close the fluid passage, and a light-transmission plate which is installed on an opening formed in the blocking plate and transmits light between the inlet and the outlet in a closed state of the blocking plate, and a vacuum system including the same.

### TECHNICAL FIELD

The present invention relates to a vacuum gate valve, which is installed in a vacuum system and opens or closes a passage of a fluid, and a vacuum system including the same.

### BACKGROUND ART

Generally, a vacuum system in which a material can be deposited on a substrate in a vacuum state is used in a semiconductor manufacturing process or display manufacturing process, and the vacuum system includes a vacuum chamber, a vacuum pump, a vacuum valve, a vacuum gauge, an evaporation source, various driving apparatuses, and the like.

In such a vacuum system, vacuum valves are mainly mounted between vacuum pumps, between a vacuum pump and a vacuum chamber, and between vacuum chambers and perform a function of opening or closing a fluid passage.

Particularly, vacuum gate valves are mainly installed between a vacuum pump and a vacuum chamber and between vacuum chambers and provided to open or close a fluid passage in a valve body by a moving operation of a blocking plate (gate).

While the vacuum gate valve is closed, the blocking plate blocks the fluid passage in the valve body, and a driving state of an apparatus (for example, a vacuum pump) installed at an opposite side thereof cannot be visually checked, which causes inconvenience in inspection and maintenance of a vacuum system.

In addition, when a vacuum system is applied to a process for particle acceleration, an optical unit using an optical system may be installed in a vacuum chamber, and the optical system alignment of the optical unit is performed by changing a state of a vacuum gate valve to an open state and emitting light toward the optical unit from the outside of the vacuum chamber. In some cases, the optical unit should be aligned in a vacuum state, a state of the vacuum gate valve should be changed to an open state to emit light, and thus there is a limitation that it is impossible to align the optical system of the optical unit in a vacuum environment.

### DISCLOSURE

### Technical Problem

The present invention is directed to providing a vacuum gate valve which allows a state of an apparatus installed at an opposite side to be visually checked in a closed state of the valve and an optical system of an optical unit installed in a vacuum chamber to be aligned in a vacuum state.

Technical objectives to be achieved by the present invention are not limited to the above-described objectives, and other objectives which are not described above will be clearly understood to those skilled in the art to which the present invention belongs through the following descriptions.

### Technical Solution

In accordance with one aspect of the present invention, there is provided a vacuum gate valve including a valve body in which an inlet and an outlet are formed, a blocking plate formed on a fluid passage between the inlet and the outlet, a driving unit which is installed on the valve body to be connected to the blocking plate and moves the blocking plate to open or close the fluid passage, and a light-transmission plate which is installed on an opening formed in the blocking plate and transmits light between the inlet and the outlet in a closed state of the blocking plate.

In addition, the light-transmission plate may be formed of at least one of glass, soda-lime glass (SLG), fused silica (SiO₂), CaF, sapphire (Al₂O₃), zinc sulfide (ZnS), zinc selenide (ZnSe), and NaCl.

In addition, a sealing member may be installed between the light-transmission plate and the blocking plate.

In addition, the vacuum gate valve may further include a fixing part for fixing the light-transmission plate to the blocking plate.

In addition, the fixing part may include a fixing frame which covers an edge portion of the light-transmission plate and a screw fastener screw-coupled to a thread formed on the blocking plate.

In addition, the fixing part may include a fixing frame which covers an edge portion of the light-transmission plate and bolt fixing parts formed at a plurality of locations of the fixing frame.

In addition, the fixing frame may be formed of a metal or ceramic material.

In addition, the fixing part may include a female thread formed in the opening of the blocking plate and a male thread formed on the light-transmission plate and fastened to the female thread;

In addition, the male thread may be formed on a protrusion protruding from a lower surface of the light-transmission plate, and a sealing member may be formed between the lower surface of the light-transmission plate and the blocking plate.

Meanwhile, in accordance with another aspect of the present invention, there is provided a vacuum system including a first vacuum chamber, a first pipe connected to the first vacuum chamber, and the vacuum gate valve installed in the first pipe.

In addition, the vacuum system may further include a second pipe connected to the vacuum gate valve and a second vacuum chamber connected to the second pipe, wherein an optical unit including an optical system which is to be aligned with incident light may be installed in at least one of the first and second vacuum chambers.

In addition, a light source may be installed outside any one of the first and second vacuum chambers, and a light receiver for receiving light which is emitted from the light source and passes through the first and second vacuum chambers may be installed outside the other of the first and second vacuum chambers.

### Advantageous Effects

According to an embodiment of the present invention, as a light-transmission plate is installed on a blocking plate of a vacuum gate valve, there are effects that, even while the valve is closed, an apparatus (for example, vacuum pump) installed at an opposite side can be visually checked, and an optical system of an optical unit installed in a vacuum chamber can be aligned in a vacuum state.

### DESCRIPTION OF DRAWINGS

FIGS. 1 and 2 are schematic views of a vacuum gate valve according to one embodiment of the present invention.

FIG. 3 is a front view of a blocking plate according to one embodiment of the present invention.

FIG. 4 is a cross-sectional view of the blocking plate illustrated in FIG. 3.

FIG. 5 is a front view of a blocking plate according to another embodiment of the present invention.

FIG. 6 is a cross-sectional view of the blocking plate illustrated in FIG. 5.

FIG. 7 is a cross-sectional view of a blocking plate according to still another embodiment of the present invention.

FIG. 8 is a schematic view of a vacuum system according to one embodiment of the present invention.

### REFERENCE NUMERALS

| | |
|---|---|
| 100: VACUUM GATE VALVE | 110: VALVE BODY |
| 111: FLUID PASSAGE | 112: DRIVING UNIT |
| 120: BLOCKING PLATE | 130: LIGHT-TRANSMISSION PLATE |
| 140: FIXING PART | 141: FIXING FRAME |
| 142: SCREW FASTENER | 143: BOLT FIXING PART |
| 144: BOLT | 145: FEMALE THREAD |
| 146: MALE THREAD | 150: SEALING MEMBER |
| 200: VACUUM SYSTEM | 210: FIRST VACUUM CHAMBER |
| 211: FIRST PIPE | 220: SECOND VACUUM CHAMBER |
| 221: SECOND PIPE | 300: OPTICAL UNIT |
| 410: LIGHT SOURCE | 420: LIGHT RECEIVER |

### MODES OF THE INVENTION

Since the present invention may be variously modified and have several embodiments, specific embodiments will be illustrated in the accompanying drawings and described in detail. However, this is not intended to limit the present invention to the specific embodiments, and it should be appreciated that all changes, equivalents, and substitutes falling within the spirit and technical scope of the present invention are encompassed in the present invention. In the description of the embodiments, certain detailed descriptions of the related art will be omitted when it is deemed that they may unnecessarily obscure the gist of the inventive concept.

While terms such as “first” and “second” may be used to describe various components, such components are not limited by the above terms. These terms are used only to distinguish one component from another.

Terms used herein are only for the purpose of describing particular embodiments and are not intended to limit the present invention. Singular forms are intended to include the plural forms, unless the context clearly indicates otherwise. In the present specification, it should be understood that the terms “comprise,” “comprising,” “include,” and/or “including” used herein specify the presence of stated features, numbers, steps, operations, elements, components, and/or combinations thereof but do not preclude the presence or addition of one or more other features, numbers, steps, operations, elements, components, and/or combinations thereof.

Hereinafter, an embodiment of a vacuum gate valve and a vacuum system including the same will be described in detail with reference to the accompanying drawings, and when the embodiment is described with reference to the accompanying drawings, components which are the same or correspond to each other will be denoted by the same reference numerals, and redundant description thereof will be omitted.

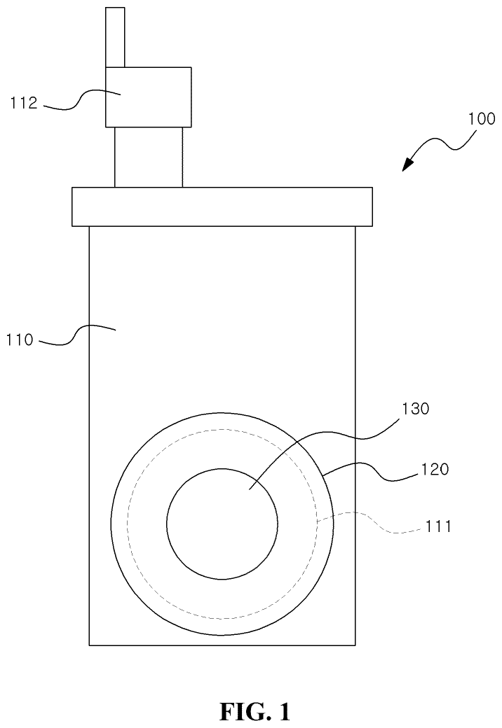

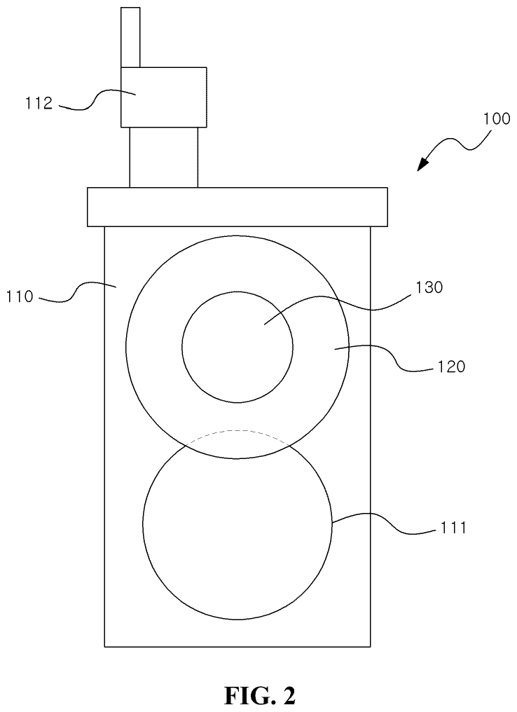

FIGS. 1 and 2 are schematic views of a vacuum gate valve according to one embodiment of the present invention, wherein FIG. 1 shows a closed state of the vacuum gate valve, and FIG. 2 shows an open state of the vacuum gate valve.

A vacuum gate valve 100 according to the present embodiment includes a valve body 110, a blocking plate 120, a driving unit 112, and a light-transmission plate 130.

The valve body 110 includes an inlet through which a fluid is introduced and an outlet through which the fluid is discharged, and a fluid passage 111 is formed between the inlet and the outlet.

The blocking plate (gate) 120 is movably installed on the fluid passage 111 and configured to open or close the fluid passage 111 according to a position of the blocking plate (gate) 120. According to the present invention, the blocking plate 120 may be configured to move vertically and may move upward to change a state of closing the fluid passage 111 as in FIG. 1 to a state of opening the fluid passage 111 as in FIG. 2.

According to the present invention, an opening 121 (see FIG. 4) is formed in the blocking plate 120 to pass through the blocking plate 120.

The driving unit 112 is installed on the valve body 110 to be connected to the blocking plate 120 and moves the blocking plate 120 to open or close the fluid passage 111. The driving unit 112 may operate in a manual manner in which a user manipulates a handle for driving or in an electric manner in which an operation is automatically performed by an electrical signal.

The light-transmission plate 130 is installed on the opening 121 formed in the blocking plate 120 and configured to transmit light between the inlet and the outlet in a closed state of the blocking plate 120.

Various materials may be used for the light-transmission plate 130 according to a wavelength band of light to be transmitted. For example, when visible light needs to be transmitted, the light-transmission plate 130 may be formed of a glass material, a soda-lime glass (SLG) material, or the like. In addition, when a transmission wavelength band ranges from 0.17 to 3.3 μm, the light-transmission plate 130 may be formed of fused silica (SiO₂), when a transmission wavelength band ranges from 0.13 to 12 μm, the light-transmission plate 130 may be formed of CaF, when a transmission wavelength band ranges from 0.15 to 5.5 μm, the light-transmission plate 130 may be formed of sapphire (Al₂O₃), when a transmission wavelength band ranges from 0.37 to 14.0 μm, the light-transmission plate 130 may be formed of zinc sulfide (ZnS), when a transmission wavelength band ranges from 0.5 to 22 μm, the light-transmission plate 130 may be formed of zinc selenide (ZnSe), and when a transmission wavelength band ranges from 250 nm to 16 μm, the light-transmission plate 130 may be formed of NaCl.

As described above, as the light-transmission plate 130 is installed on the blocking plate 120 of the vacuum gate valve 100, even while the valve is closed, a state of an apparatus (for example, a vacuum pump) installed at an opposite side can be visually checked, and thus convenience of the inspection and maintenance of the vacuum system is provided.

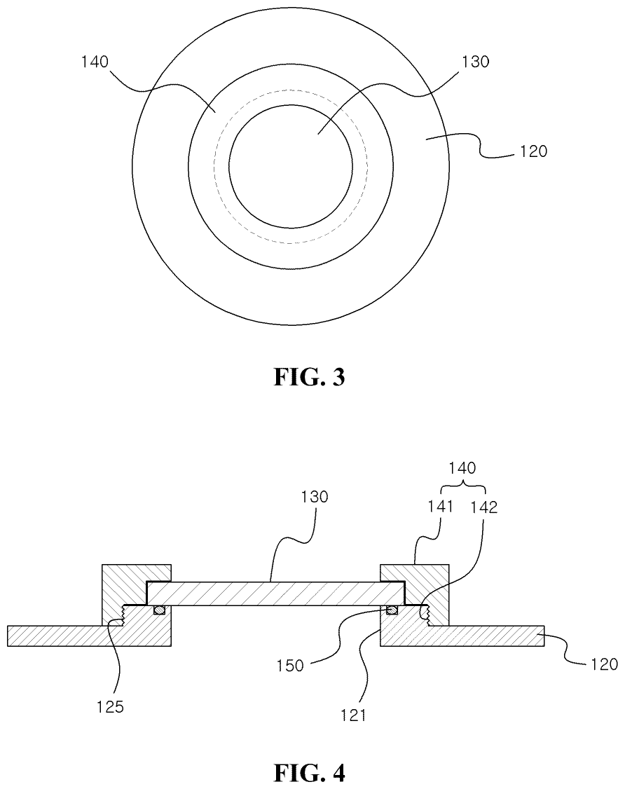

FIG. 3 is a front view of the blocking plate according to one embodiment of the present invention, and FIG. 4 is a cross-sectional view of the blocking plate illustrated in FIG. 3.

Referring to FIGS. 3 and 4, the blocking plate 120 may further include a fixing part 140 for fixing the light-transmission plate 130.

The fixing part 140 may include a fixing frame 141 which covers an edge portion of the light-transmission plate 130 and a screw fastener 142 screw-coupled to a thread 125 formed on the blocking plate 120. The fixing frame 141 may be coupled to the blocking plate 120 to prevent separation of the light-transmission plate 130 and formed of a metal material or ceramic material.

A sealing member 150 such as an O-ring may be installed between the light-transmission plate 130 and the blocking plate 120 to seal a gap between the light-transmission plate 130 and the blocking plate 120 and formed of a stretchable rubber material or synthetic resin material. The sealing member 150 may be installed to be seated on a seating groove formed in the blocking plate 120, the light-transmission plate 130 may be installed on the sealing member 150, and then the fixing frame 141 may be screw-coupled to the blocking plate 120 so that the light-transmission plate 130 can be fixed to the blocking plate 120.

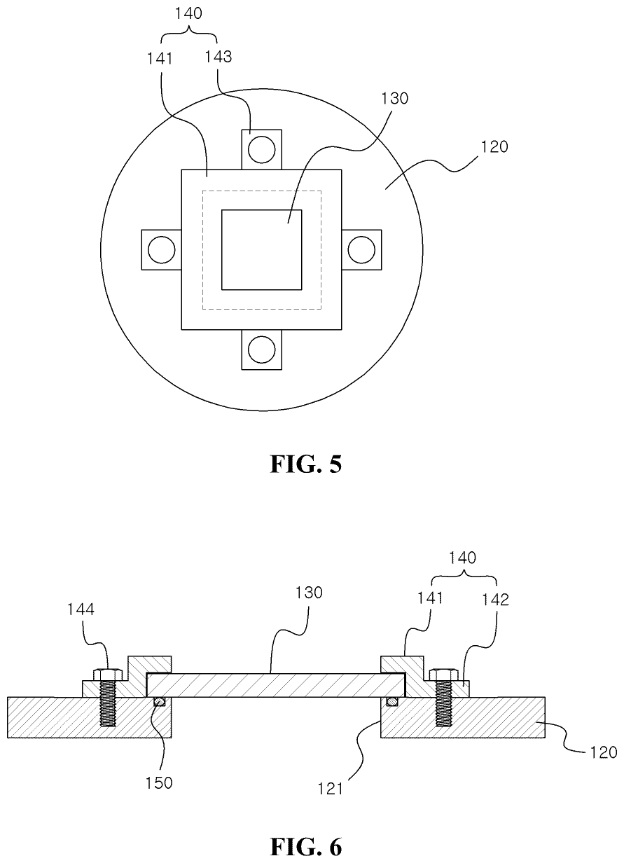

FIG. 5 is a front view of a blocking plate according to another embodiment of the present invention, and FIG. 6 is a cross-sectional view of the blocking plate illustrated in FIG. 5.

In the case of the previous embodiment, an example of the light-transmission plate 130 having a circular plate shape has been described, but the shape of the light-transmission plate 130 may be variously changed. In the case of the present invention, an example of a light-transmission plate 130 having a quadrangular plate shape will be described.

In addition, in the case of the present invention, a modified example of a fixing part 140 is provided, and the fixing part 140 includes a fixing frame 141 which covers an edge portion of a light-transmission plate 130 and bolt fixing parts 143 formed at a plurality of locations of the fixing frame 141.

When the light-transmission plate 130 has a quadrangular plate shape as in the present invention, the fixing frame 141 may also have a quadrangular frame shape, and the bolt fixing parts 143 may be formed on edge portions of a quadrangular frame.

A sealing member 150 may also be formed in a quadrangular gasket shape. In a state in which the sealing member 150 is installed in a blocking plate 120, the light-transmission plate 130 and the fixing frame 141 are installed on the blocking plate 120, and bolts 144 are fastened to the bolt fixing parts 143 to couple the fixing frame 141 to the blocking plate 120.

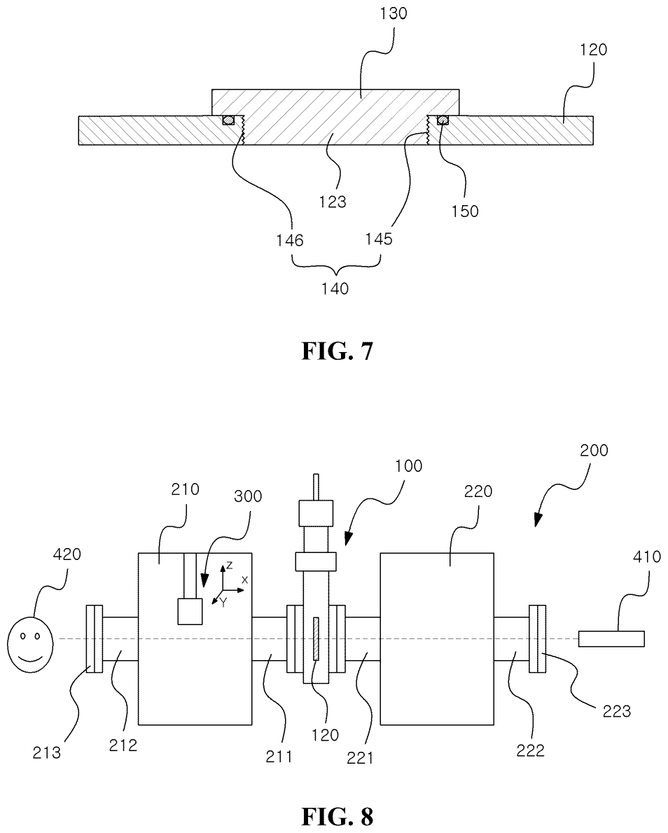

FIG. 7 is a cross-sectional view of a blocking plate according to still another embodiment of the present invention.

In the case of the present invention, a fixing frame 141 is not installed, and a fixing part 140 is formed between a blocking plate 120 and a light-transmission plate 130. The fixing part 140 may include a female thread 145 formed in an opening of the blocking plate 120 and a male thread 146 formed on the light-transmission plate 130.

The male thread 146 is formed on an outer circumference of a protrusion 123 protruding from a lower surface of the light-transmission plate 130, and the male thread 144 of the protrusion 123 is screw-coupled to the female thread 145 of the blocking plate 120 to fix the light-transmission plate 130. Like the previous embodiments, a sealing member 150 may be installed between the lower surface of the light-transmission plate 130 and the blocking plate 120.

FIG. 8 is a schematic view of a vacuum system according to one embodiment of the present invention.

Referring to FIG. 8, a vacuum system 200 according to the present embodiment includes a first vacuum chamber 210, a first pipe 211 connected to the first vacuum chamber 210, and a vacuum gate valve 100 installed in the first pipe 211.

A vacuum pump, a vacuum gauge, and the like may be connected to the first vacuum chamber 210, and the vacuum gate valve 100 has the above-described structure. After a vacuum state is created in an inner space of the first vacuum chamber 210 using the vacuum pump, the vacuum gate valve 100 may be closed to maintain a vacuum atmosphere.

A second vacuum chamber 220 may be connected to one side of the vacuum gate valve 100 through a second pipe 221, and an optical unit 300 including an optical system capable of being aligned with incident light may be installed at at least one of the first and second vacuum chambers 210 and 220. In the case of the present invention, an example in which the optical unit 300 is installed in the first vacuum chamber 210 is described.

A third pipe 212 may be connected to the first vacuum chamber 210 at a side opposite to that of the vacuum gate valve 100, and a fourth pipe 222 may be connected to the second vacuum chamber 220 at a side opposite to that of the vacuum gate valve 100. Covers 213 and 223 in which visible windows are formed may be installed in the third pipe 212 and the fourth pipe 222, wherein checking may be performed from the outside through the visible windows.

For optical system alignment of the optical unit 300, a light source 410 (for example, a laser source) may be installed outside any one of the first and second vacuum chamber 210 and 220, and a light receiver 420 (for example, the eyes of a human or an optical detector) for receiving light which is emitted from the light source 410 and passes through the first and second vacuum chambers 210 and 220 may be disposed outside the other of the first and second vacuum chambers 210 and 220.

For example, when an inner portion of the first vacuum chamber 210 is in a vacuum state, and an inner portion of the second vacuum chamber 220 is not in a vacuum state, in a case in which the optical system alignment of the optical unit 300 is needed, the light source 410 emits light toward the optical unit 300 while the vacuum gate valve 100 is closed, that is, a blocking plate 120 blocks a fluid passage 111. Accordingly, the light of the light source 410 passes through the light-transmission plate 130 of the blocking plate 120, is incident on the optical unit 300, passes through the optical system and the visible window of the cover 213, and is received by the light receiver 420. The optical system of the optical unit 300 can be aligned using optical information of the light received by the light receiver 420.

While the present invention has been described above with reference to exemplary embodiments, it may be understood by those skilled in the art that various modifications and changes of the present invention may be made within a range not departing from the spirit and scope of the present invention defined by the appended claims.

1. A vacuum gate valve comprising:
a valve body in which an inlet and an outlet are formed;
a blocking plate formed on a fluid passage between the inlet and the outlet;
a driving unit which is installed on the valve body to be connected to the blocking plate and moves the blocking plate to open or close the fluid passage; and
a light-transmission plate which is installed on an opening formed in the blocking plate and transmits light between the inlet and the outlet in a closed state of the blocking plate.

2. The vacuum gate valve of claim 1, wherein the light-transmission plate is formed of at least one of glass, soda-lime glass (SLG), fused silica (SiO₂), CaF, sapphire (Al₂O₃), zinc sulfide (ZnS), zinc selenide (ZnSe), and NaCl.

3. The vacuum gate valve of claim 1, wherein a sealing member is installed between the light-transmission plate and the blocking plate.

4. The vacuum gate valve of claim 1, further comprising a fixing part for fixing the light-transmission plate to the blocking plate.

5. The vacuum gate valve of claim 4, wherein the fixing part includes:
a fixing frame which covers an edge portion of the light-transmission plate; and
a screw fastener screw-coupled to a thread formed on the blocking plate.

6. The vacuum gate valve of claim 4, wherein the fixing part includes:
a fixing frame which covers an edge portion of the light-transmission plate; and
bolt fixing parts formed at a plurality of locations of the fixing frame.

7. The vacuum gate valve of claim 5, wherein the fixing frame is formed of a metal or ceramic material.

8. The vacuum gate valve of claim 4, wherein the fixing part includes:
a female thread formed in the opening of the blocking plate; and
a male thread formed on the light-transmission plate and fastened to the female thread.

9. The vacuum gate valve of claim 8, wherein:
the male thread is formed on a protrusion protruding from a lower surface of the light-transmission plate; and
a sealing member is formed between the lower surface of the light-transmission plate and the blocking plate.

10. A vacuum system comprising:
a first vacuum chamber;
a first pipe connected to the first vacuum chamber; and
a vacuum gate valve according to claim 1 which is installed in the first pipe.

11. The vacuum system of claim 10, further comprising:
a second pipe connected to the vacuum gate valve; and
a second vacuum chamber connected to the second pipe,
wherein an optical unit including an optical system, which is to be aligned with incident light, is installed in at least one of the first and second vacuum chambers.

12. The vacuum system of claim 11, wherein:
a light source is installed outside any one of the first and second vacuum chambers; and
a light receiver for receiving light, which is emitted from the light source and passes through the first and second vacuum chambers, is installed outside the other of the first and second vacuum chambers.
